(19) United States
(12) Patent Application Publication
(10) Pub. No.: US 2025/0140741 A1
(43) Pub. Date: May 1, 2025

(54) PACKAGE ARCHITECTURE WITH THERMAL ENHANCEMENTS FOR VERTICALLY ORIENTED INTEGRATED CIRCUIT DIES

(71) Applicant: Intel Corporation, Santa Clara, CA (US)

(72) Inventors: Rajiv Mongia, Portland, OR (US); Sagar Suthram, Portland, OR (US); Wilfred Gomes, Portland, OR (US); Ravindranath Vithal Mahajan, Chandler, AZ (US); Nicolas Butzen, Portland, OR (US)

(73) Assignee: Intel Corporation, Santa Clara, CA (US)

(21) Appl. No.: 18/494,023

(22) Filed: Oct. 25, 2023

(51) Int. Cl. H01L 25/065; H01L 23/00; H01L 23/467; H01L 23/473; H01L 23/522; H10B 80/00

(52) U.S. Cl. CPC H01L 25/0652; H01L 23/467; H01L 23/473; H01L 23/5226; H01L 24/08; H01L 24/32; H10B 80/00; H01L 2224/08137; H01L 2224/08145; H01L 2224/32155

(57) ABSTRACT

Embodiments of a microelectronic assembly comprise: a first set comprising one or more of first integrated circuit (IC) dies; a second set comprising another one or more of the first IC dies; a plate between, and in direct contact with, the first set and the second set; and a second IC die coupled to the first set, the second set, and the plate. Each IC die comprises a substrate of semiconductor material and an interconnect region including metallization in interlayer dielectric (ILD), the substrate and the interconnect region share a planar interface, and the first IC dies and the second IC die are arranged with the planar interfaces of the first IC dies parallel to each other and orthogonal to the planar interface of the second IC die.

### BACKGROUND

Electronic circuits, when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a schematic cross-sectional view of an example microelectronic assembly with thermal enhancements for vertically oriented IC dies according to some embodiments of the present disclosure.

FIG. 1B is a schematic cross-sectional view of certain details of the microelectronic assembly of FIG. 1A.

FIG. 1C is a schematic cross-sectional view of certain other details of the microelectronic assembly of FIG. 1A.

FIG. 1D is a schematic cross-sectional view of certain other details of the microelectronic assembly of FIG. 1A.

FIG. 2 is a schematic cross-sectional view of another example microelectronic assembly with thermal enhancements for vertically oriented IC dies according to some embodiments of the present disclosure.

FIG. 3 is a schematic cross-sectional view of yet another example microelectronic assembly with thermal enhancements for vertically oriented IC dies according to some embodiments of the present disclosure.

FIG. 4 is a schematic cross-sectional view of yet another example microelectronic assembly with thermal enhancements for vertically oriented IC dies according to some embodiments of the present disclosure.

FIG. 5 is a schematic cross-sectional view of yet another example microelectronic assembly with thermal enhancements for vertically oriented IC dies according to some embodiments of the present disclosure.

FIG. 6 is a schematic cross-sectional view of yet another example microelectronic assembly with thermal enhancements for vertically oriented IC dies according to some embodiments of the present disclosure.

FIG. 7 is a schematic cross-sectional view of yet another example microelectronic assembly with thermal enhancements for vertically oriented IC dies according to some embodiments of the present disclosure.

FIG. 8 is a schematic cross-sectional view of yet another example microelectronic assembly with thermal enhancements for vertically oriented IC dies according to some embodiments of the present disclosure.

FIG. 9 is a schematic cross-sectional view of yet another example microelectronic assembly with thermal enhancements for vertically oriented IC dies according to some embodiments of the present disclosure.

FIG. 10A is a schematic cross-sectional view of yet another example microelectronic assembly with thermal enhancements for vertically oriented IC dies according to some embodiments of the present disclosure.

FIG. 10B is a schematic plan view of the example microelectronic assembly of FIG. 10A.

FIG. 11 is a schematic perspective view of a portion of a microelectronic assembly according to some embodiments of the present disclosure.

FIGS. 12A-12C are schematic cross-sectional views of example structures in microelectronic assembly according to some embodiments of the present disclosure.

FIG. 13 is a schematic cross-sectional view of yet another example microelectronic assembly with thermal enhancements for vertically oriented IC dies according to some embodiments of the present disclosure.

FIG. 14 is a schematic cross-sectional view of yet another example microelectronic assembly with thermal enhancements for vertically oriented IC dies according to some embodiments of the present disclosure.

FIG. 15 is a schematic cross-sectional view of yet another example microelectronic assembly with thermal enhancements for vertically oriented IC dies according to some embodiments of the present disclosure.

FIG. 16 is a schematic cross-sectional view of yet another example microelectronic assembly with thermal enhancements for vertically oriented IC dies according to some embodiments of the present disclosure.

FIG. 17 is a schematic cross-sectional view of yet another example microelectronic assembly with thermal enhancements for vertically oriented IC dies according to some embodiments of the present disclosure.

FIG. 18 is a top view of a wafer that includes one or more semiconductor dies of the microelectronic package in accordance with any of the embodiments disclosed herein.

FIG. 19 is a cross-sectional view of a device package that includes one or more microelectronic assemblies in accordance with any of the embodiments disclosed herein.

FIG. 20 is a cross-sectional side view of a device assembly that includes one or more microelectronic assemblies in accordance with any of the embodiments disclosed herein.

FIG. 21 is a block diagram of an example computing device that includes one or more microelectronic assemblies in accordance with any of the embodiments disclosed herein.

### DETAILED DESCRIPTION

### Overview

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in any way to limit the broad scope of the present disclosure and its potential applications.

The trend in the computer industry is to utilize multiple processors in large servers, the multiple processors being coupled together in a single package, such as a Multi-Chip Module (MCM). The multiple processors along with other IC dies containing memory circuits (e.g., cache memory circuits, high-bandwidth memory circuits, etc.) are interconnected by high-speed data buses in the package substrate of the MCM, for example, to enable the totality of processors to operate together. However, current technology in such MCMs is inherently limited in its ability to scale to the bandwidth/distance requirements of next generation servers that could have signal speeds greater than 10 GHz and/or data speeds of 3-10 Terabytes per second. The limitations are primarily associated with bandwidth reduction, signal delay, signal loss, and signal distortion due to various reasons, one of which is the configuration in which the multiple processors are coupled together inside the package.

Current packaging architecture, whether 2D, 2.5D or 3D, utilizes multiple IC dies that are oriented parallel to each other and interconnected by various kinds of interconnects, such as copper microbumps, solder balls, etc. In a general sense, any typical IC die consists of a substrate, an active region in the substrate comprising transistors and other active circuitry, and a metallization stack over the substrate, sharing a contact area with the active region. The metallization stack is the region of the IC die in which the individual devices (e.g., transistors, capacitors, resistors, etc.) are interconnected with conductive traces and conductive vias. Common metals used for the conductive traces and conductive vias are copper and aluminum. The metallization stack typically includes contact pads, insulating layers (e.g., interlayer dielectric (ILD) materials such as silicon oxide), conductive layers comprising the conductive traces, and bonding sites for chip-to-chip or chip-to-package connections. Modern IC dies may include more than 10 conductive layers in the metallization stack.

Conventionally, various such IC dies may be stacked within a package in various ways: (1) back-to-back, in which the substrate of one IC die is in direct contact with the substrate of another IC die; (2) back-to-front, in which the substrate of one IC die is in direct contact with the metallization stack of the other IC die; and (3) front-to-front, in which the metallization stacks of the two IC dies are in direct contact. In all these configurations, the IC dies are mutually parallel to each other, with the active circuitry disposed in planes parallel to the contacting areas of adjacent IC dies. Such architecture suffers from certain inherent limitations. For example, compute IC dies comprising high-performance compute circuitry that generates a lot of heat have to be placed on the top of any such stack so that heat can be dissipated properly. Such placement limits the number of high-power compute IC dies that can be stacked in a package having a limited (or constrained) footprint.

Technological advancements to enable higher density of circuitry in a smaller footprint include attaching IC dies in an orthogonal orientation relative to the IC die. In such an orientation, the active regions of some IC dies, which lie along a planar interface parallel to the surface of each IC die, are orthogonal to the active regions of some other IC dies. IC die to IC die interconnections in such configurations exist not only in an XY plane (e.g., with the base IC die), but also in a XZ plane (e.g., with other IC dies in the orthogonal stack) of a cartesian coordinate system having mutually orthogonal axes X, Y, and Z.

However, such orthogonal stacking can create a substantial thermal bottleneck during operation. Some IC dies, such as compute dies, generate heat during operation. When orthogonally stacked, the thermal paths for heat dissipation in such compute dies can be longer than with conventional stacking, depending on the size of the compute dies and the number of IC dies stacked orthogonally, with thermal paths being orthogonally along the lengths (or widths) rather than the thickness. In typical semiconductor dies, the thickness can be much smaller than the length (or width), and in a stack (depending on the number of IC dies stacked), the thickness can range in a few hundred micrometers whereas the length (or width) may be in a range of a few millimeters. Such longer thermal pathways can lead to slower heat dissipation and higher chances of electrical performance degradation from heat. For example, where the number of orthogonally stacked IC dies exceeds two in a compute-centric product, or four-eight in a memory-centric product, heat dissipation becomes a substantial design concern for maintaining optimum performance of the microelectronic assembly.

Accordingly, embodiments described herein enable a microelectronic assembly having a sandwich structure of active silicon and thermal spreader layers to enhance the orthogonal heat transport of an orthogonally oriented 3D stack of IC dies. The spreaders may comprise a selection from a variety of materials such as silicon (with thermal conductivity of 120 W/m/K), silicon carbide (with thermal conductivity in a range between 360 W/m/K and 490 W/m/K), and polycrystalline or single-crystal carbon (e.g., diamond with thermal conductivity in a range between 1500 W/m/K and 3000 W/m/K) to allow for variable thermal capabilities while maintaining a reasonable cost. Use of different materials can allow for different thermal capabilities, allowing for higher compute/memory density. Different configurations while integrating the vertical die stack into a package with other compute elements may also be implemented to enhance thermal performance. Such configurations as described herein may enable higher compute or memory densities (compared to other configurations) without encountering thermal limitations that would require substantial infrastructure changes to support higher thermal needs.

Some embodiments of the microelectronic assembly described herein comprise a first set comprising one or more of first IC dies; a second set comprising another one or more of the first IC dies; a thermally conductive plate (i.e. having more thermal conductivity than a thermal insulator such as polystyrene) between, and in direct contact with, the first set and the second set; and a second IC die coupled to the first set, the second set, and the plate. Each IC die comprises a substrate of semiconductor material and an interconnect region including metallization in interlayer dielectric (ILD), the substrate and the interconnect region share a planar interface, and the first IC dies and the second IC die are arranged with the planar interfaces of the first IC dies parallel to each other and orthogonal to the planar interface of the second IC die.

Embodiments of an IC die assembly described herein comprise a first set of one or more of first IC dies; a second set of another one or more of the first IC dies; a plate between, and in direct contact with, the first set and the second set; and a second IC die coupled to the first set, the second set, and the plate. Each IC die comprises a substrate of semiconductor material and an interconnect region including metallization in ILD, the substrate and the interconnect region share a planar interface, the first IC dies and the second IC die are arranged with the planar interfaces of the first IC dies parallel to each other and orthogonal to the planar interface of the second IC die, and the plate comprises structures to transfer heat away from the first set and the second set. In some such embodiments, the structures comprise cooling channels that can enhance the compute density by four times or more as compared to the embodiments without the channels. In some embodiments, a heat sink such as a metallic lid may be modified to provide a liquid distribution manifold for circulating liquid coolant through the different channels in various spreaders in the IC die assembly. Some example manifold structures include single loop for continuous flow of coolant in separate spreaders individually; manifold single pass with parallel flow structures in different structures and unified inlet and outlet in the metallic lid; and microchannels selected from a variety of materials such as silicon, silicon carbide and copper.

Yet other embodiments of a microelectronic assembly described herein comprise a set of one or more of first IC dies; a second IC die coupled to the set; and a third IC die adjacent to the set of first IC dies and coupled to the second IC die. Each IC die comprises a substrate of semiconductor material and an interconnect region including metallization in ILD, the substrate and the interconnect region share a planar interface, and the first IC dies, the second IC die and the third IC die are arranged such that the planar interfaces of the first IC dies are parallel to each other and orthogonal to the planar interfaces of the second IC die and the third IC die, and the planar interfaces of the second IC die and the third IC die are parallel to each other.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type pr P-type materials. Dies may include, for example, a crystalline base material formed using a bulk silicon (or other bulk semiconductor material) or a silicon-on-insulator (SOI) structure. In some other embodiments, the base material of one or more of the IC dies may comprise alternate materials, which may or may not be combined with silicon that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “optical structure” includes arrangements of forms fabricated in ICs to receive, transform and/or transmit optical signals as described herein. It may include optical conductors such as waveguides, electromagnetic radiation sources such as lasers and light-emitting diodes (LEDs) and electro-optical devices such as photodetectors.

In various embodiments, any photonic IC (PIC) described herein may comprise a semiconductor material including, for example, N-type or P-type materials. The PIC may include, for example, a crystalline base material formed using a bulk silicon (or other bulk semiconductor material) or a SOI structure (or, in general, a semiconductor-on-insulator structure). In some embodiments, the PIC may be formed using alternative materials, which may or may not be combined with silicon, that include, but are not limited to, lithium niobite, indium phosphide, silicon dioxide, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-N or group IV materials. In some embodiments, the PIC may comprise a non-crystalline material, such as polymers. In some embodiments, the PIC may be formed on a printed circuit board (PCB). In some embodiments, the PIC may be inhomogeneous, including a carrier material (such as glass or silicon carbide) as a base material with a thin semiconductor layer over which is an active side comprising transistors and like components. Although a few examples of the material for the PIC are described here, any material or structure that may serve as a foundation upon which the PIC may be built falls within the spirit and scope of the present disclosure.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field effect transistors (FETs), e.g., MOSFETs. In many embodiments, an FET is a four-terminal device. In SOI, or nanoribbon, or gate all-around (GAA) FET, the FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides, including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO₂), borosilicate (e.g., 70-80 wt % SiO₂, 7-13 wt % of B₂O₃, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates, and PCBs such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a package substrate may refer to a substrate that includes buildup layers (e.g., ABF layers).

The term “metallization stack” may be used to refer to a stack of one or more interconnects for providing connectivity to different circuit components of an IC die/chip and/or a package substrate.

As used herein, the term “pitch” of interconnects refers to a center-to-center distance between adjacent interconnects.

In context of a stack of dies coupled to one another or in context of a die coupled to a package substrate, the term “interconnect” may also refer to, respectively, die-to-die (DTD) interconnects and die-to-package substrate (DTPS) interconnects. DTD interconnects may also be referred to as first-level interconnects (FLI). DTPS interconnects may also be referred to as Second-Level Interconnects (SLI).

Although not specifically shown in all of the present illustrations in order to not clutter the drawings, when DTD or DTPS interconnects are described, a surface of a first die may include a first set of conductive contacts, and a surface of a second die or a package substrate may include a second set of conductive contacts. One or more conductive contacts of the first set may then be electrically and mechanically coupled to some of the conductive contacts of the second set by the DTD or DTPS interconnects.

In some embodiments, the pitch of the DTD interconnects may be different from the pitch of the DTPS interconnects, although, in other embodiments, these pitches may be substantially the same.

The DTPS interconnects disclosed herein may take any suitable form. In some embodiments, a set of DTPS interconnects may include solder (e.g., solder bumps or balls that are subject to a thermal reflow to form the DTPS interconnects). DTPS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTPS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects in a microelectronic assembly or an IC package as described herein may be metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some metal-to-metal interconnects, a dielectric material (e.g., silicon oxide, silicon nitride, silicon carbide) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the dies on either side of a set of DTD interconnects may be bare (e.g., unpackaged) dies.

In some embodiments, the DTD interconnects may include solder. For example, the DTD interconnects may include conductive bumps or pillars (e.g., copper bumps or pillars) attached to the respective conductive contacts by solder. In some embodiments, a thin cap of solder may be used in a metal-to-metal interconnect to accommodate planarity, and this solder may become an intermetallic compound during processing. In some embodiments, the solder used in some or all of the DTD interconnects may have a higher melting point than the solder included in some or all of the DTPS interconnects. For example, when the DTD interconnects in an IC package are formed before the DTPS interconnects are formed, solder-based DTD interconnects may use a higher-temperature solder (e.g., with a melting point above 200 degrees Celsius), while the DTPS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth), tin, silver, bismuth, indium, indium and tin, or gallium.

In some embodiments, a set of DTD interconnects may include an anisotropic conductive material, such as any of the materials discussed above for the DTPS interconnects. In some embodiments, the DTD interconnects may be used as data transfer lanes, while the DTPS interconnects may be used for power and ground lines, among others.

In microelectronic assemblies or IC packages as described herein, some or all of the DTD interconnects may have a finer pitch than the DTPS interconnects. In some embodiments, the DTPS interconnects disclosed herein may have a pitch between about 80 microns and 300 microns, while the DTD interconnects disclosed herein may have a pitch between about 0.5 microns and 100 microns, depending on the type of the DTD interconnects. An example of silicon-level interconnect density is provided by the density of some DTD interconnects. In some embodiments, the DTD interconnects may have too fine a pitch to couple to the package substrate directly (e.g., too fine to serve as DTPS interconnects). The DTD interconnects may have a smaller pitch than the DTPS interconnects due to the greater similarity of materials in the different dies on either side of a set of DTD interconnects than between a die and a package substrate on either side of a set of DTPS interconnects. In particular, the differences in the material composition of dies and package substrates may result in differential expansion and contraction of the die dies and package substrates due to heat generated during operation (as well as the heat applied during various manufacturing operations). To mitigate damage caused by this differential expansion and contraction (e.g., cracking, solder bridging, etc.), the DTPS interconnects in any of the microelectronic assemblies or IC packages as described herein may be formed larger and farther apart than DTD interconnects, which may experience less thermal stress due to the greater material similarity of the pair of dies on either side of the DTD interconnects.

It will be recognized that one more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photo-imageable polymers, dry film photo-imageable polymers, acrylics, solvents) may be provided in an IC package described herein and may not be labeled or shown to avoid cluttering the drawings. Solder resist may be a liquid or dry film material including photo-imageable polymers. In some embodiments, solder resist may be non-photo-imageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

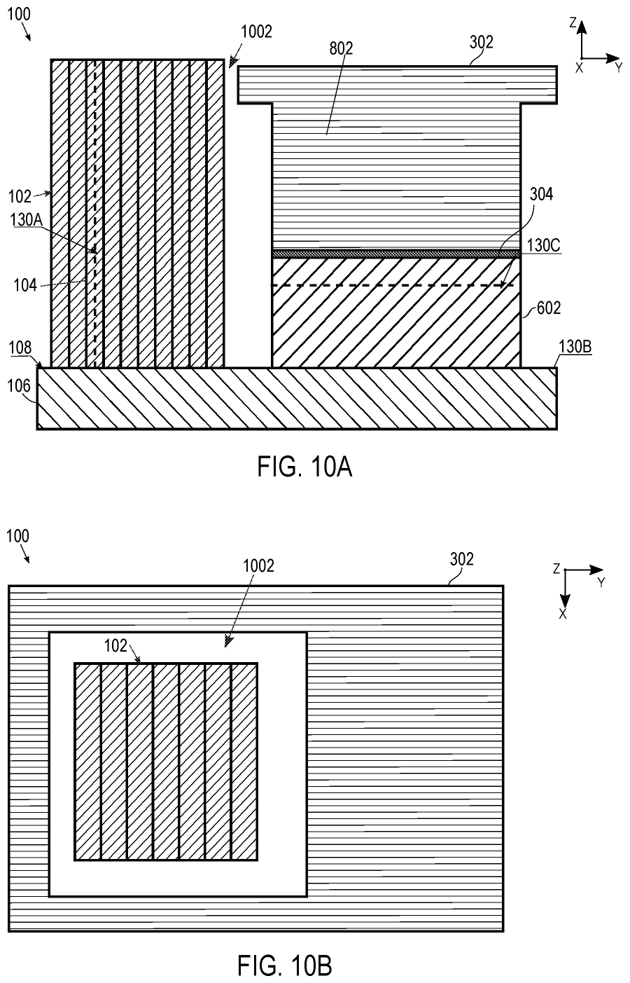

For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 112a-112e), such a collection may be referred to herein without the letters (e.g., as “112”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### Example Embodiments

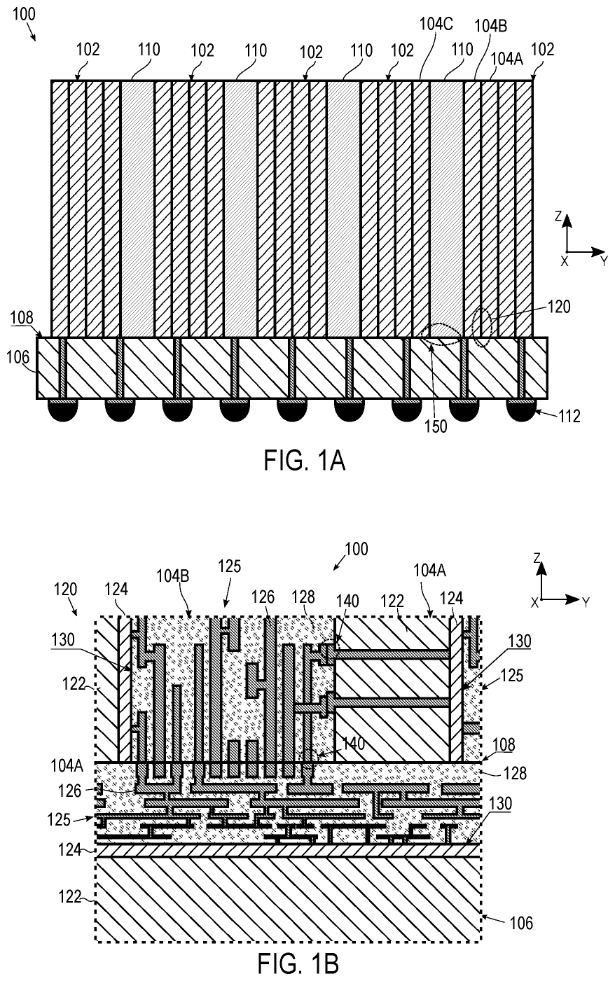

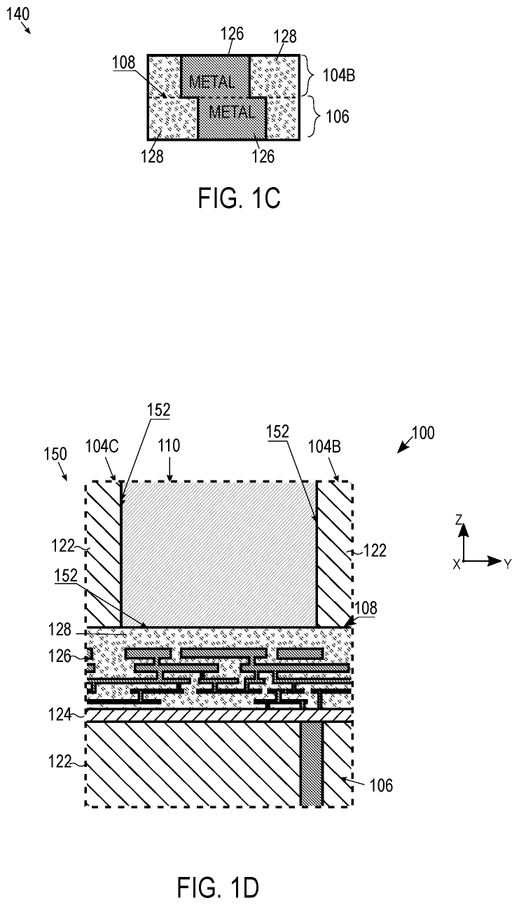

FIG. 1A is a schematic cross-sectional view of an example microelectronic assembly 100 according to some embodiments of the present disclosure. Microelectronic assembly 100 comprises a set 102 having one or more of IC dies 104 attached orthogonally to another IC die 106 on a surface 108 of IC die 106. Note that the figure shows a plurality of IC dies 104 in set 102; in some other embodiments, set 102 may contain a single one of IC die 104. Adjacent sets 102 may be separated by a thermally conductive heat spreader 110. In some embodiments, heat spreader 110 may be disposed between every other one of set 102. Heat spreader 110 may comprise a plate in some embodiments, having two sets of mutually parallel sides perpendicular to a base and a top and orthogonal to each other. In various embodiments, heat spreader 110 may comprise an electrically insulating and thermally conducting material such as silicon, silicon carbide, or single crystal or polycrystalline carbon such as industrial diamond. Note that as used herein, crystalline carbon includes both single crystal carbon (such as single crystal diamond) and polycrystalline carbon (such as polycrystalline diamond). As shown by the Cartesian coordinate axes X, Y, and Z, IC dies 104 in each set 102 are coupled to each other along the XZ plane, whereas IC dies 104 are coupled to IC die 106 in the XY plane. Note that for the sake of clarity of explanation only, different ones of IC dies 104 are labeled as 104a, 104b, 104c, etc. In some embodiments, they may comprise identical structures with the same functionalities. In other embodiments, one or more of them may be different from the any of the others in structures and/or functionalities. Each one of IC dies 104 may range between 0.5 millimeters and 5 millimeters along the Z-axis and likewise in the X-axis and may range between 25 microns and 500 microns along the Y-axis in different embodiments. In some embodiments, all IC dies 104 may be of comparable dimensions along the three axes, whereas in other embodiments, one or more IC dies 104 may be smaller than some others, along one or more axes.

Heat generated in IC dies 104 is conducted primarily along the Y-axis (i.e., the XY plane and YZ plane) to heat spreader 110. Within heat spreader 110, heat is conducted in a direction away from IC die 106 along the Z-axis (i.e., the XZ plane and the YZ plane). In some embodiments, heat may be generated in IC die 106 also and may be conducted away from IC die 106 through heat spreader 110. Note that there may be marginal thermal conduction through IC dies 104, however, because heat spreader 110 may comprise a material with higher thermal conductivity than IC dies 104, heat may be preferentially transferred through heat spreader 110. In various embodiments, IC die 106 may be coupled by interconnects 112 to a PCB (not shown). Interconnects 112 may comprise SLIs as described in the previous subsection in some embodiments. IC die 106 as also one or more IC dies 104 may include various structures therein as described in reference to a detail 120 in FIG. 1B.

FIG. 1B shows a schematic cross-sectional view of detail 120 proximate to the interfaces between IC dies 104a, 104b, and 104 according to some embodiments of the present disclosure. Each of IC dies 104a, 104b, and 104 may include a semiconductor substrate 122. In some embodiments, substrate 122 may comprise an active region 124 including transistors, diodes, and other such active circuitry (as opposed to passive circuitry such as traces, resistors and capacitors). In some other embodiments, active region 124 may be absent. For example, active region 124 may be present in IC dies 104a and 104b and may be absent in IC die 106; in such embodiments, IC die 106 may function as a bridge die providing conductive pathways between one or more of set 102. In another example, IC dies 104a, 104b and 104 may include active region 124 (as shown); in some such embodiments, IC die 106 may have additional functionalities, such as providing an intra-package network-on-chip between two or more of set 102, or power delivery, or some other functionalities.

Substrate 122 may be in direct contact with an interconnect region 125 comprising metallization 126 in ILD 128. Examples of semiconductor substrate 122, metallization 126 and ILD 128 are as described in the previous subsection. Metallization 126 may comprise conductive traces between layers of ILD 128 and conductive vias through layers of ILD 128. Metallization 126 may also include bond-pads (or conductive traces/vias) exposed on surfaces of IC dies 104 along the XZ plane and XY plane. A planar interface 130 between substrate 122 and interconnect region 125 may be in the XZ plane for IC dies 104a and 104b and in the XY plane for IC die 106. IC dies 104 may be thus arranged in microelectronic assembly 100 such that planar interfaces 130 of IC dies 104 in set 102 are orthogonal to planar interface 130 of IC die 106. In various embodiments, IC dies 104 in any one set 102 may be coupled to each other by interconnects 140, which may comprise hybrid bonds. IC dies 104 may be coupled to IC die 106 by interconnects 140, comprising hybrid bonds in some examples.

FIG. 1C shows details of a hybrid bond interconnect 140. FIG. 1C is a schematic cross-sectional view of a detail of a particular one of interconnects 140 in microelectronic assembly 100. Note that although interconnect 140 is shown only between IC dies 104b and 106, the structure may be similar to other such interconnects comprising hybrid bonds in microelectronic assembly 100, for example interconnect 140 between IC dies 104a and 104b. In a general sense, interconnect 140 may comprise metal-metal bonds between metallization 126 of IC dies 104b and 104, and dielectric-dielectric bonds (e.g., oxide-oxide bonds) between ILD 128 of IC dies 104b and 104. In the embodiment shown, the portions of metallization 126 in the hybrid bonds in IC die 104b may comprise portion of conductive traces exposed on the lateral surface of the die proximate to surface 108 of IC die 106; corresponding portions of metallization 126 in IC die 106 may comprise conventional conductive structures electroplated on surface 108. In embodiments where interconnect 140 is between IC dies 104a and 104b, for example, the respective portions of metallization 126 in either IC die 104 may be conventional conductive structures electroplated on the respective surfaces thereof. In some embodiments, dielectric material of ILD 128 of IC dies 104b and 104 may be the same as each other; in other embodiments, dielectric material of ILD 128 of IC dies 104b and 104 may be different from each other. The hybrid bonds may provide electrical and mechanical coupling between IC dies 104b and 106. In various embodiments, interconnects 140 may have a linear dimension of less than 5 micrometers and a pitch of less than 10 micrometers between adjacent interconnects.

Turning back to FIG. 1B, IC dies 104 may be coupled to each other such that interconnect region 125 of one of IC dies 104, for example, IC die 104a, may be in direct contact with substrate 122 of adjacent IC die 104, for example, 104b in a back-to-front configuration (as shown). In some such embodiments, substrate 122 of IC die 104a may include conductive through-substrate vias (TSVs) conductively coupling metallization 126 of IC die 104b with active region 124 (and/or metallization 126) of IC die 104a. In some embodiments (not shown), substrate 122 of IC dies 104a and 104b may be in contact in a back-to-back configuration. In some other embodiments (not shown), interconnect regions 125 of adjacent IC dies 104a and 104b may be in direct contact in a front-to-front configuration. Any such configuration may be included in microelectronic assembly 100 within the broad scope of the embodiments.

FIG. 1D is a simplified cross-sectional view of a detail 150 of FIG. 1A, proximate to a region at the interfaces between heat spreader 110, IC dies 104b, 104c, and IC die 106. In various embodiments, heat spreader 110 may be bonded to substrate 122 of IC dies 104b and 104c along opposite surfaces 152 of heat spreader 110. Surfaces 152 may be along the XZ plane in the orientation shown. Depending on the material of heat spreader 110, the bond may be a silicon-silicon bond, silicon carbide-silicon bond or carbon-silicon bond. In some other embodiments where IC dies 104b and 104c are turned around so that respective interconnect regions 125 are in contact with heat spreader 110 along surfaces 152, the bond formed thereon may comprise silicon oxide, silicon carbide-oxide and/or carbon-silicon oxide bond. In various embodiments, heat spreader 110 may be bonded to ILD 128 of IC die 106 along surface 108 in the XY plane. Note that surface 108 is orthogonal to surface 152. Depending on the material of heat spreader 110, the bond may be a silicon oxide bond, silicon carbide-oxide bond or carbon-silicon oxide bond.

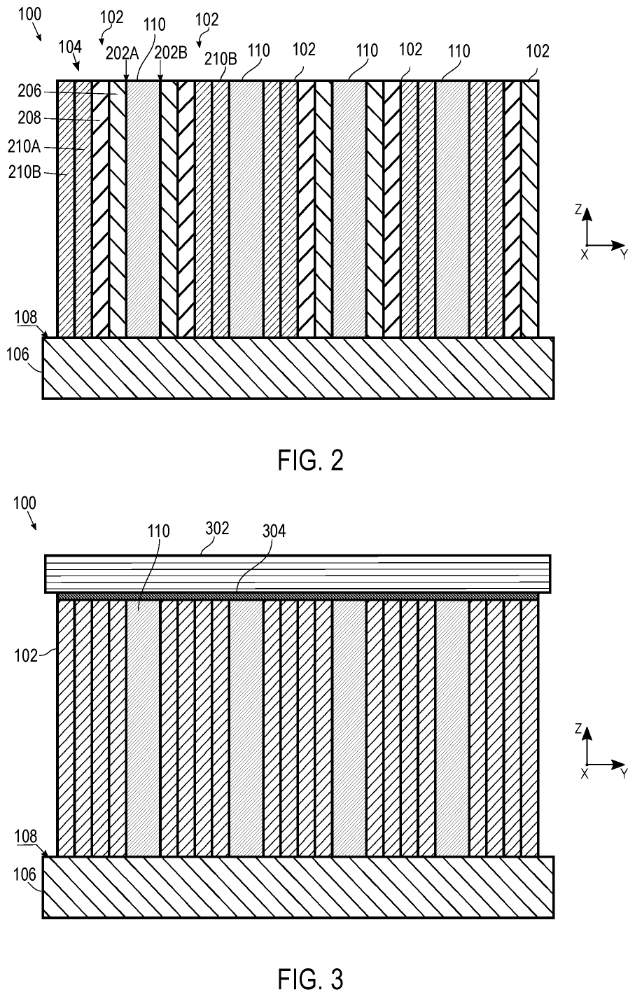

FIG. 2 is a simplified block diagram illustrating another embodiment of microelectronic assembly 100. Each IC die 104 in any one set 102 may comprise structures corresponding to functionalities different from one or more other IC dies 104 in the same set 102. Dies 104 may be arranged in each set 102 to enable efficient heat transfer therefrom. For example, the IC die 104 generating the highest amount of heat during operation may be placed closest to heat spreader 110. In the example shown, each set 102 comprises a system-on-chip (SOC) 206, a voltage regulator (VR) 208 and memory dies 210a and 210b. SOC 206 may generate the highest amount of heat during operation, followed by VR 208, followed by memory dies 210a and 210b. Each set 102 may be arranged around heat spreader 110 to be mirror images of each other in terms of functionalities (or alternatively, corresponding heat generation capabilities) of IC dies 104 therein. For example, in the configuration shown, SOC die 206 is adjacent to and in direct contact with heat spreader 110; and voltage regulator 208 is between SOC 206 and memory die 210a. In the embodiment shown, memory die 208b is also in direct contact with heat spreader 110 on an opposite side of SOC 206 of the same set 102. In some other embodiments, heat spreader 110 may be absent between adjacent memory dies 210 of adjacent sets 102. Various such configurations are encompassed within the broad scope of the embodiments herein. Note that in the figure, interconnects 112 of IC die 106 are not shown merely for ease of illustration and not as a limitation.

FIG. 3 is a simplified block diagram of an embodiment of microelectronic assembly 100. A heat sink 302 (also called an integrated heat spreader (IHC)) may be disposed on a side of set 102 opposite to IC die 106. In various embodiments, heat sink 302 may comprise a metal lid made of, for example, copper. Other metallic materials or metallic composites may also be used in heat sink 302 within the broad scope of the embodiments. A thermal interface material (TIM) 304 may enable adhesion of set 102 and heat spreader 110 to heat sink 302. TIM 304 may also comprise a metallic material such as solder. In some other embodiments, TIM 304 comprises a thermally conductive adhesive polymer material including silicone or hydrocarbon oil-based thermal grease. In some embodiments TIM 304 may comprise hybrid polymers (also called polymer hybrids) that contain more than one type of polymer. In various such embodiments, TIM 304 may comprise at least one polymer. In some embodiments, TIM 304 may comprise thermally conductive particulate fillers in a matrix of lower thermal conductivity polymer material so that the composite thermal conductivity of TIM 304 is approximately 7 W/m° K (or higher). Particulate fillers in some such embodiments include aluminum oxide, magnesium oxide, aluminum nitride, boron nitride, diamond powder, or encapsulated liquid metal particles. Metal fillers, for example silver, may also be used.

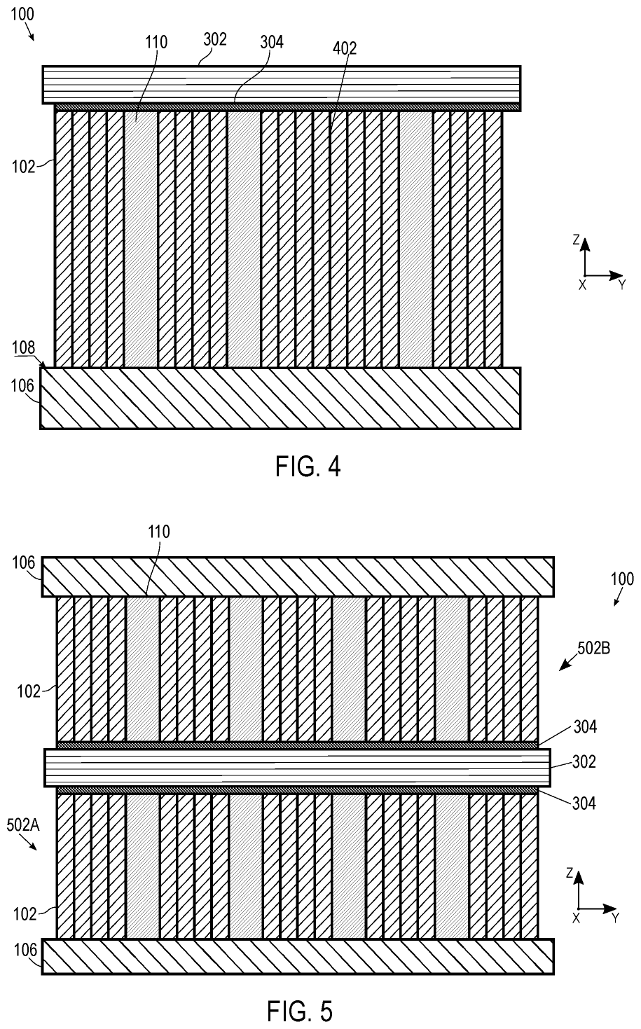

FIG. 4 is a simplified block diagram of an embodiment of microelectronic assembly 100. In some embodiments, heat spreader 110 may not be uniformly distributed between adjacent sets 102 comprising similarly sized stacks of IC dies 104. In some other embodiments, adjacent sets 102 may comprise differently sized stacks of IC dies 104 (i.e., number of IC dies 104 may be different in adjacent sets 102). In some such embodiments, an interface 402 between adjacent sets 102 or between IC dies 104 of similarly sized stacks may not include any heat spreader 110.

FIG. 5 is a simplified block diagram of another embodiment of microelectronic assembly 100. Sets 102, heat spreader 110 and IC die 106 may together constitute a sub-assembly 502. In the example embodiment shown, two such sub-assemblies 502a and 502b may be disposed on either side of heat sink 302, coupled thereto by TIM 304. In the configuration shown, IC dies 106 of each sub-assembly 502 may be distant from heat sink 302. Heat sink 302 may be comprised of features that allow for flow of a fluid (e.g., coolant in liquid and/or gaseous states) in order to dissipate heat from the assembly. Liquids can include water, solution of water and antifreeze, engineered fluids, or fluids that undergo a phase change (e.g., 2-phase loops). Gaseous coolants can consist of air, nitrogen, carbon dioxide, or engineered materials.

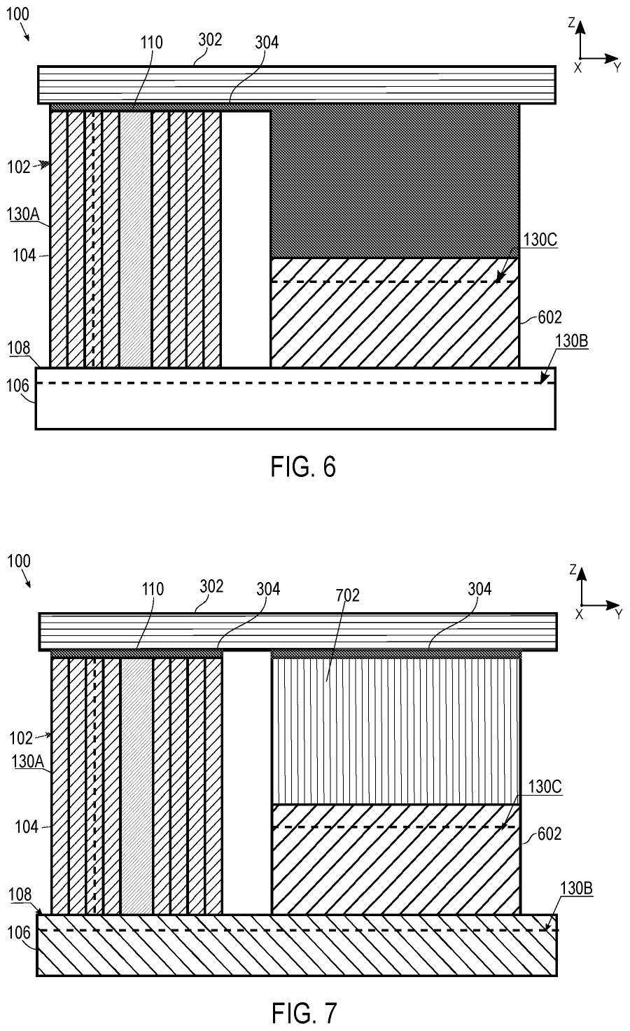

FIG. 6 is a simplified block diagram of yet another embodiment of microelectronic assembly 100. Another IC die 602 may be coupled to IC die 106 on surface 108 adjacent to set 102. Planar interfaces 130a, 130b and 130 between substrates 122 (not shown) and interconnect regions 125 (not shown) of IC dies 104, 106 and 602, respectively, may be mutually oriented as follows. Planar interface 130a may be orthogonal to planar interfaces 130b and 130c. Planar interfaces 130b and 130c may be mutually parallel. Note that only one planar interface 130a of IC dies 104 is shown; it may be understood that other IC dies 104 in sets 102 may have planar interfaces parallel to planar interface 130a. IC die 602 may be coupled to IC die 106 by FLIs or SLIs, depending on the relative size and pitch of the interconnects. In the embodiment shown, sets 102 may be longer in the Z-axis than IC die 602. In some such embodiments, TIM 304 may be extended to fill in the space between IC die 602 and heat sink 302 to enable heat sink 302 to be planar and parallel to IC die 106. In some such embodiments, the shape of TIM 304 above IC die 602 may not be uniform and straight-edged as shown in the figure. However, in terms of thermal functionalities, TIM 304 may enable heat transfer from IC die 602 to heat sink 302 suitably. In some embodiments, IC die 602 may be a SOC, sets 102 may comprise memory dies and IC die 106 may be a network-on-chip die.

FIG. 7 is a simplified block diagram of yet another embodiment of microelectronic assembly 100. IC die 602 may be coupled to IC die 106 on surface 108 adjacent to set 102. Planar interfaces 130a, 130b and 130 between substrates 122 (not shown) and interconnect regions 125 (not shown) of IC dies 104, 106 and 602, respectively, may be mutually oriented as described in reference to FIG. 6. IC die 602 may be coupled to IC die 106 by FLIs or SLIs, depending on the relative size and pitch of the interconnects. In the embodiment shown, sets 102 may be longer in the Z-axis than IC die 602. In some such embodiments, a filler structure comprising a dummy (i.e., inactive) silicon piece 702 may be attached to IC die 602 and may be disposed between heat sink 302 and IC die 602. TIM 304 may be used to attach silicon piece 702 to heat sink 302, providing a thermally conductive path through silicon piece 702 from IC die 106 to heat sink 302.

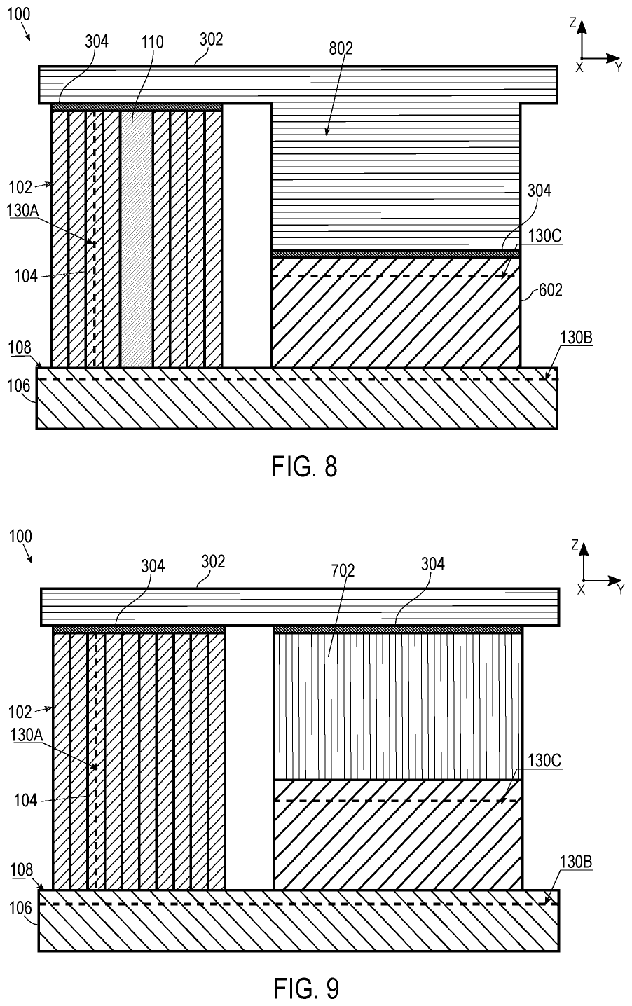

FIG. 8 is a simplified block diagram of yet another embodiment of microelectronic assembly 100. The embodiment shown is similar to those of FIGS. 6 and 7, except that heat sink 302 includes a pedestal 802 that may be sized to close any gap between IC dies 602 and 104 along the Z-axis. TIM 304 may be used to thermally couple pedestal 802 of heat sink 302 to IC die 602.

FIG. 9 is a simplified block diagram of yet another embodiment of microelectronic assembly 100. The embodiment shown is similar to those of FIG. 7, except that heat spreader 110 is absent among IC dies 104. Some such embodiments may be used where IC dies comprise memory dies, IC die 602 is a SOC die, and IC die 106 has network-on-chip functionality.

FIG. 10A is a simplified block diagram of yet another embodiment of microelectronic assembly 100. The embodiment shown is similar to that of FIG. 8, except that heat sink 302 includes an opening 1002 around set 102 of IC dies 104. In some embodiments, IC dies 104 may extend through opening 1002; in some other embodiments, IC dies 104 may be shorter than top surface of heat sink 302 along the Z-axis. In some embodiments, instead of pedestal 802, dummy silicon 702 may be present (e.g., similar to embodiment shown in FIG. 7) along with opening 1002 in heat sink 302. In some embodiments, heat spreader 110 may also be present between two sets 102 of IC dies 104.

FIG. 10B is a plan view of the embodiment shown in FIG. 10A. In some embodiments, opening 1002 may extend around set 102 of IC dies 104. In some embodiments, more than one such set 102 may be provisioned in microelectronic assembly 100, and opening 1002 may surround each such set 102 suitably.

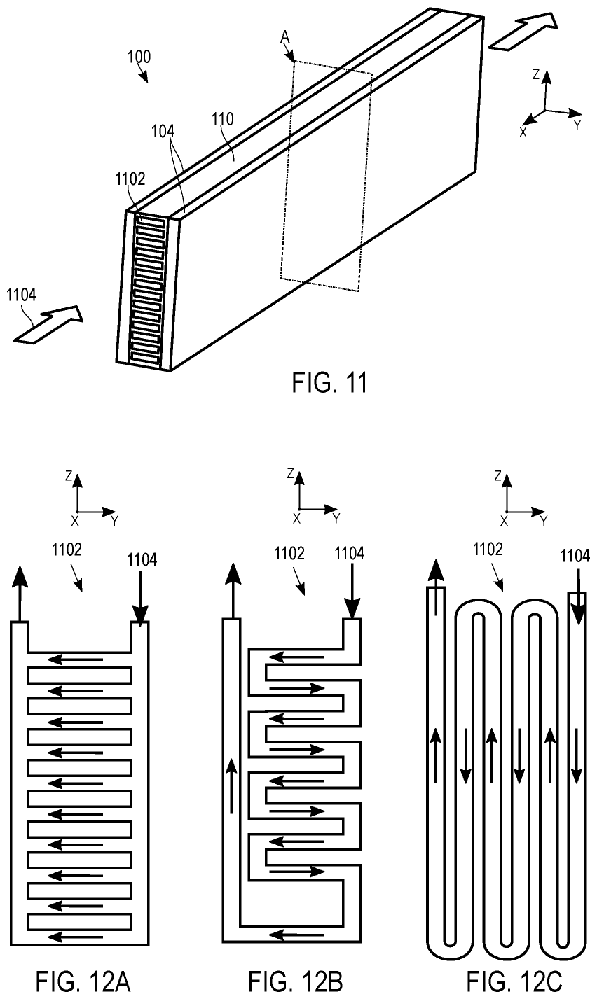

FIG. 11 is a simplified block diagram showing a perspective view of a portion of yet another embodiment of microelectronic assembly 100. Heat spreader 110 sandwiched between two IC dies 104 may include channels 1102 therein to transport a fluid coolant 1104, for example, to enhance the orthogonal heat transport of the orthogonally oriented stack. Cooling channels 1102 may be integrated into heat spreader 110 by a number of mechanisms (e.g., using different configurations, designs, processes, etc.) to create targeted cooling and to allow for proper distribution of coolant 1104 through different manifolds and feeding structures. Coolant 1104 may be a gaseous coolant (e.g., air), or a liquid coolant (e.g., water, solutions of glycol, etc.). Channels 1102 may have any suitable cross-sectional shape and structure (e.g., circular, rectangular, trapezoidal, etc.) based on particular needs as desired. In some embodiments, heat spreader 110 may include pin-fins or other structures that enhance heat transfer.

In various embodiments, channels 1102 may comprise spaced between plates of different materials, such as silicon, silicon carbide, or copper. In some embodiments, channels 1102 may comprise spaces within a mesh formed of orthogonally arranged metal plates. In yet other embodiments, channels 1102 may comprise spaces between grooves formed in plates comprising metal, silicon, silicon carbide, etc. In some other embodiments, channels 1102 may be fabricated as microchannels within a solid block of silicon, silicon carbide or other such thermally conductive and electrically insulating material. In some embodiments, a single pair of inlet and exit manifolds may be provided to permit coolant 1104 to enter and exit heat spreader 110; in other embodiments, a plurality of pairs of inlet and exit manifolds may be provided in a single heat spreader 110 to facilitate efficient heat transfer by coolant 1104 through channels 1102.

In such embodiments, coolant 1104 may be circulated through channels 1102 to transfer heat in a direction away from IC die 106 (e.g., towards heat sink 302) (e.g., channels 1102 may be oriented to facilitate such directional heat transfer; coolant 1104 may be pumped to facilitate such directional heat transfer, etc.). In some embodiments, coolant 1104 may undergo phase change within channels 1102, transforming from liquid to gaseous state between the inlet and the outlet. Coolant 1104 may recondense external to microelectronic assembly 100 in some such embodiments.

FIGS. 12A-12C show example structures of different channels 1102 in heat spreader 110 as viewed along a cross-section A in the YZ plane of FIG. 11. Note that although only three such examples are shown, channels 1102 may be provided in any suitable configuration based on thermal needs, ease of fabrication and other criteria based on particular needs. In one example as shown in FIG. 12A, channels 1102 may comprise spaces between plates in the XY plane stacked along the Z-axis with spaces between them for flow of coolant 1104. Inlet and exit manifolds may be provided in the XZ plane so that coolant 1104 flows along the Y-axis in each channel 1102. Note that in some embodiments, the inlet and exit manifolds may be provided in the YZ plane so that coolant 1104 flows along the X-axis in each channel 1102.

FIG. 12B shows another example structure of channels 1102 in heat spreader 110 as viewed along a cross-section A in the YZ plane of FIG. 11. Channels 1102 may comprise serpentine shapes in the XY plane with inlet and exit manifolds to facilitate flow of coolant 1104. In such embodiments, the longer dimensions of the serpentine shape are parallel to planar surface 130 of IC die 106 in cross-section A.

FIG. 12C shows another example structure of channels 1102 in heat spreader 110 as viewed along a cross-section A in the YZ plane of FIG. 11. Channels 1102 may comprise serpentine shapes in the YZ plane with inlet and exit manifolds to facilitate flow of coolant 1104. In such embodiments, the longer dimensions of the serpentine shape are perpendicular to planar surface 130 of IC die 106 in cross-section A.

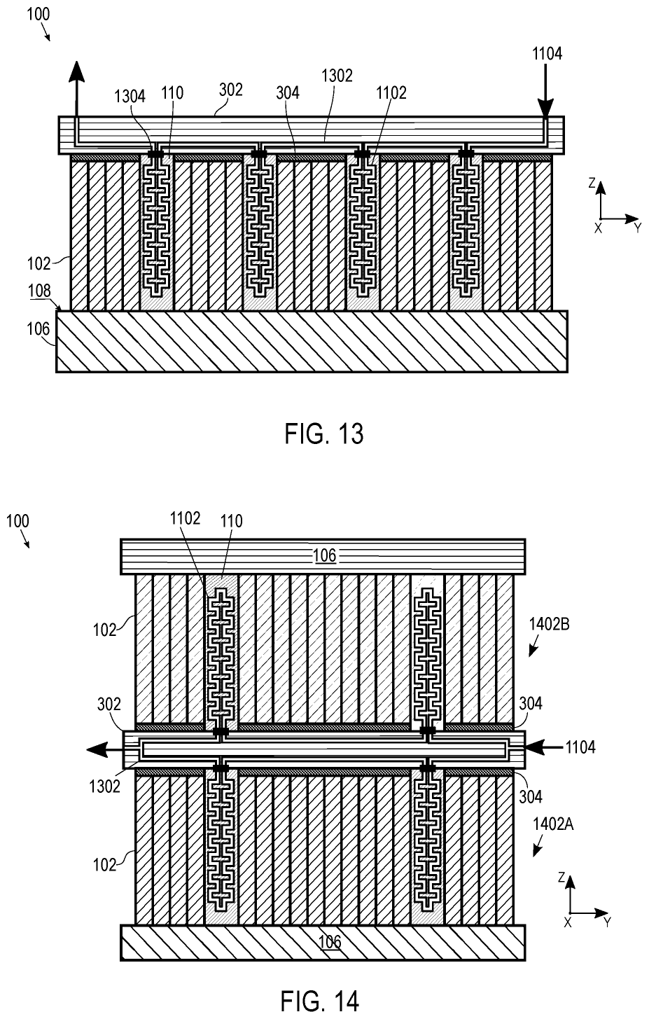

FIG. 13 is a simplified block diagram showing a cross-sectional view of an example microelectronic assembly 100 according to some embodiments. Heat sink 302 may comprise one or more channels 1302 to facilitate flow of coolant 1104. Channels 1302 may be coupled to channels 1102 in heat spreader 110 by suitable fluid ports 1304 that ensure a sealed connection without leaks. Fluid ports 1304 may comprise fluid adapters, plugs, fluid connectors, and other components suitable for enabling a leak proof or low-leak connection between channels 1102 in heat spreader 110 and channels 1302 in heat sink 302.

FIG. 14 is a simplified block diagram showing a cross-sectional view of an example microelectronic assembly 100 according to some embodiments. The embodiment shown is similar to the one of FIG. 5, except that heat spreader 110 comprises channels 1102 and heat sink 302 may comprise one or more channels 1302 to facilitate flow of coolant 1104. Channels 1302 may be coupled to channels 1102 in heat spreader 110 by suitable ports 1304 that ensure a sealed connection without leaks. Sub-assemblies 1402A and 1402B may be provisioned on either side of heat sink 302. Each one of sub-assemblies 1402A and 1402B comprises sets 102 of IC dies 104, in addition to IC die 106 and heat spreaders 110.

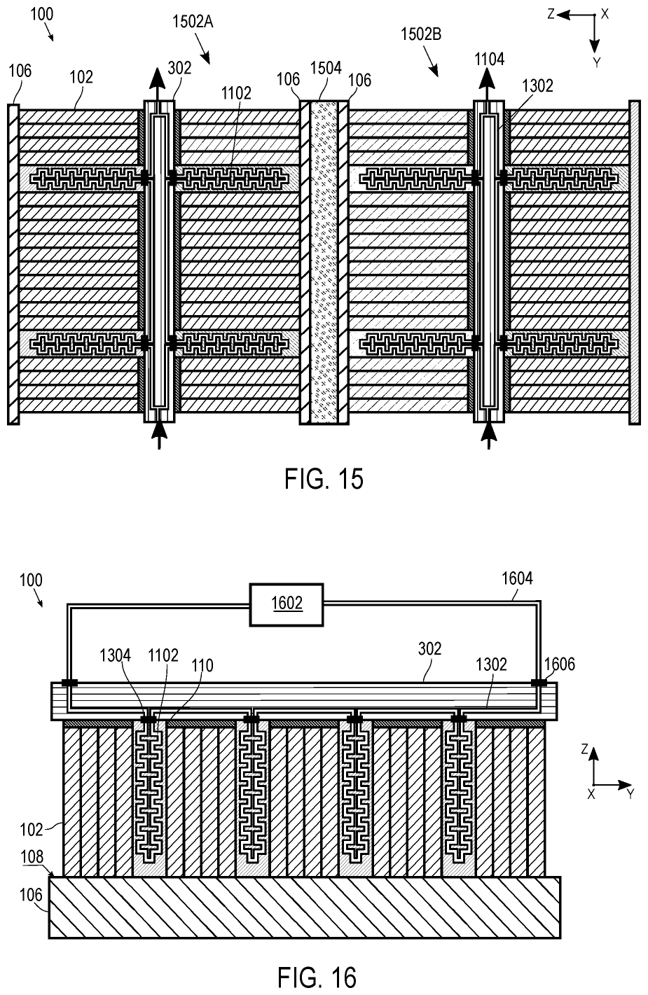

FIG. 15 is a simplified block diagram showing a cross-sectional view of an example microelectronic assembly 100 according to some embodiments. The embodiment shown is similar to the one of FIG. 14, except that multiple ones are coupled together as described further. The embodiment as shown in FIG. 14 may comprise a sub-assembly 1502. Each sub-assembly 1502 comprises sets 102 of IC dies 104, in addition to IC die 106, heat spreaders 110, and heat sink 302 with channels 1102 in heat spreaders 110 and channels 1302 in heat sink 302. Two such sub-assemblies 1502a and 1502b may be provisioned on either side of a board 1504. Board 1504 may be a general PCB in some embodiments, with conductive pathways in organic dielectric material and coupled to IC dies 106 on either side by suitable board-level interconnects (e.g., ball grid arrays, pin grid arrays, etc.). In some embodiments, board 1504 may comprise structures suitable for power delivery to sub-assemblies 1502. In other embodiments, board 1504 may comprise structures for network connectivity between sub-assemblies 1502a and 1502b. Various other functionalities may be provided to board 1504 within the broad scope of the embodiments herein.

FIG. 16 is a simplified block diagram showing a cross-sectional view of an example microelectronic assembly 100 according to some embodiments. The embodiment shown in the figure is similar to that of FIG. 14 with the addition of external components, such as a pump 1602. In various embodiments, channels 1302 may be coupled to external pipes 1604 by ports 1606. Coolant 1104 may be circulated by pump 1602 through external pipes 1604 to channels 1302 and therefrom to channels 1102 and back to pump 1602. In some embodiments, pump 1602 may comprise a micropump. In other embodiments, pump 1602 may facilitate acoustic wave based pumping. Various other structures that perform pumping functions may be encompassed in pump 1602 within the broad scope of the embodiments. In some embodiments, pump 1602 may also facilitate integration of synthetic jet based cooling system using channels 1302. Ports 1606 may comprise any suitable connector, adapter etc. that permits connection of external pipes 1604 to channels 1302 within the broad scope of the embodiments.

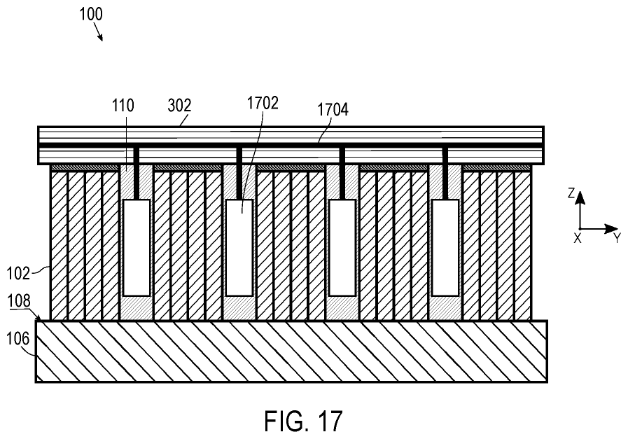

FIG. 17 is a simplified block diagram showing a cross-sectional view of an example microelectronic assembly 100 according to some embodiments. In some embodiments, heat spreader 110 may include a Peltier device 1702 that may be used for cooling IC dies 104 in sets 102. Pelter device 1702 may be electrically coupled to components external to microelectronic assembly 100 by wiring 1704 in heat sink 302.

In various embodiments, any of the features discussed with reference to any of FIGS. 1-17 herein may be combined with any other features to form a package with one or more IC dies as described herein. Some such combinations are described above, but, in various embodiments, further combinations and modifications are possible. For example, some heat spreaders 110 may comprise channels 1102 and other heat spreaders 110 may comprise Peltier device 1702, based on particular needs. In such embodiments, heat sink 302 may include wiring 1704 for Peltier device 1702 as well as channels 1302 for circulating coolant 1104. Various different embodiments described in different figures may be combined suitably based on particular needs within the broad scope of the embodiments.

### Example Devices and Components

The packages disclosed herein, e.g., any of the embodiments shown in FIGS. 1-5 or any further embodiments described herein, may be included in any suitable electronic component. FIGS. 6-9 illustrate various examples of packages, assemblies, and devices that may be used with or include any of the IC packages as disclosed herein.

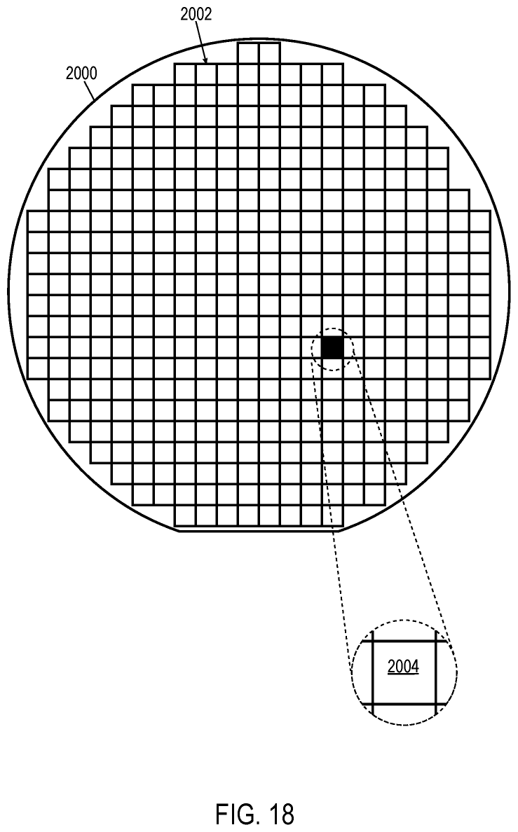

FIG. 18 is a top view of a wafer 2000 and dies 2002 that may be included in any of microelectronic assemblies 100 disclosed herein. Wafer 2000 may be composed of semiconductor material and may include one or more dies 2002 having IC structures formed on a surface of wafer 2000. The individual dies 2002 may be a repeating unit of an IC product that includes any suitable IC. After the fabrication of the semiconductor product is complete, wafer 2000 may undergo a singulation process in which dies 2002 are separated from one another to provide discrete “chips” (e.g., example die 2004) of the IC product. Example die 2004 may be any of dies 110 and 112 disclosed herein.

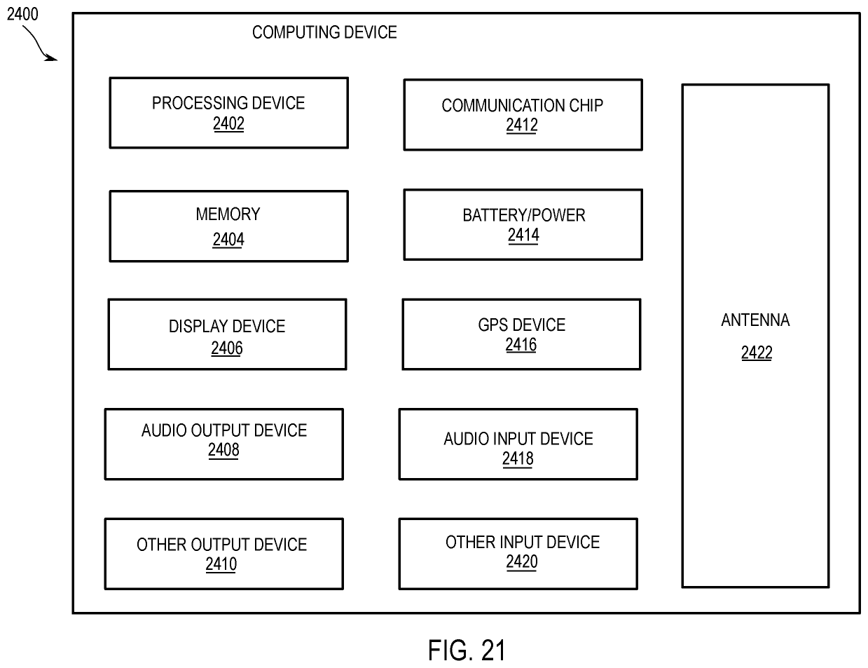

Die 2004 may include one or more transistors, supporting circuitry to route electrical signals to the transistors, passive components (e.g., signal traces, resistors, capacitors, or inductors), and/or any other IC components. In some embodiments, wafer 2000 or die 2004 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 2004. For example, a memory array formed by multiple memory devices may be formed on a same die 2004 as a processor unit (e.g., processing device 2402 of FIG. 21) or other logic that is configured to store information in the memory devices or execute instructions stored in the memory array as described in the other figures herein. Various ones of the microelectronic assemblies disclosed herein may be manufactured using a die-to-wafer assembly technique in which some dies are attached to wafer 2000 that include other dies and wafer 2000 is subsequently singulated.

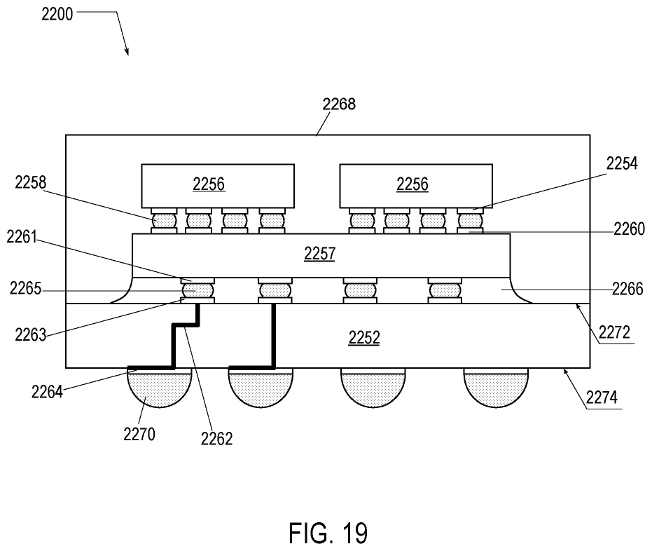

FIG. 19 is a side, cross-sectional view of an example IC package 2200 that may include IC packages in accordance with any of the embodiments disclosed herein. In some embodiments, the IC package 2200 may be a system in package (SIP). At least some of the components described in FIG. 19 may be substantially similar to the components described in the preceding figures, for example, FIG. 1.

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264 (or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261 (or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

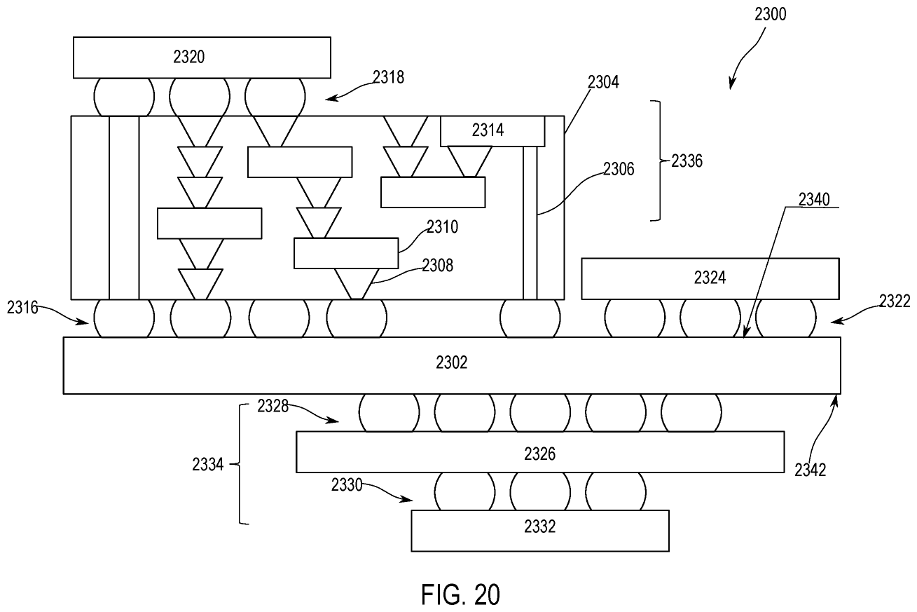

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 20.

In various embodiments, any of dies 2256 may be microelectronic assembly 100 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., HBM), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 20 is a cross-sectional side view of an IC device assembly 2300 that may include components having one or more microelectronic assembly 100 in accordance with any of the embodiments disclosed herein. At least some of the components described in FIG. 20 may be substantially similar to the components described in the preceding figures, for example, FIG. 1. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 19.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 5. In some embodiments, IC package 2320 may include at least one microelectronic assembly 100 as described herein. Microelectronic assembly 100 is not specifically shown in the figure in order to not clutter the drawing.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, ESD devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

FIG. 21 is a block diagram of an example computing device 2400 that may include one or more components having one or more IC packages in accordance with any of the embodiments disclosed herein. For example, any suitable ones of the components of computing device 2400 may include a microelectronic assembly (e.g., 100) in accordance with any of the embodiments disclosed herein. In another example, any one or more of the components of computing device 2400 may include any embodiments of IC package 2200 (e.g., as shown in FIG. 19). In yet another example, any one or more of the components of computing device 2400 may include an IC device assembly 2300 (e.g., as shown in FIG. 20).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SOC die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more DSPs, ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic RAM (DRAM)), nonvolatile memory (e.g., read-only memory (ROM)), flash memory, solid-state memory, and/or a hard drive. In some embodiments, memory 2404 may include memory that shares a die with processing device 2402. This memory may be used as cache memory and may include embedded dynamic RAM (eDRAM) or spin transfer torque magnetic RAM (STT-MRAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### Select Examples

Example 1 provides a microelectronic assembly, including a first set including one or more of first integrated circuit (IC) dies; a second set including another one or more of the first IC dies; a plate in direct contact with the first set and the second set; and a second IC die coupled to the first set, the second set, and the plate, in which: each IC die includes a substrate of semiconductor material and an interconnect region including metallization in interlayer dielectric (ILD), the substrate and the interconnect region share a planar interface, and the first IC dies and the second IC die are arranged with the planar interfaces of the first IC dies parallel to each other and orthogonal to the planar interface of the second IC die.

Example 2 provides the microelectronic assembly of example 1, in which: the first IC dies are coupled to each other by hybrid bonds including oxide-oxide and metal-metal bonds, and the first IC dies are coupled to the second IC die by at least one of: (i) hybrid bonds including oxide-oxide and metal-metal bonds, and (ii) oxide-oxide bonds.

Example 3 provides the microelectronic assembly of example 1 or 2, in which the plate is in direct contact with the respective substrates of the corresponding first IC dies in the first set and the second set.

Example 4 provides the microelectronic assembly of any one of examples 1-3, in which the plate includes at least one of: (i) silicon, (ii) a compound including silicon and carbon, and (iii) crystalline carbon.

Example 5 provides the microelectronic assembly of example 4, in which: the plate is in direct contact with the ILD of the second IC die, and the plate is bonded with the ILD of the second IC die.

Example 6 provides the microelectronic assembly of any one of examples 1-5, in which the plate includes channels that permit flow of a fluid.

Example 7 provides the microelectronic assembly of example 6, in which: the fluid is a liquid, and the liquid is to be pumped through the plate by an external pump.

Example 8 provides the microelectronic assembly of any one of examples 1-7, in which the plate is not electrically conductive.

Example 9 provides the microelectronic assembly of any one of examples 1-8, in which the substrate of the second IC die includes electrically conductive through-substrate vias (TSVs).

Example 10 provides the microelectronic assembly of any one of examples 1-9, in which: the first set and the second set each include IC dies having different structures corresponding to different functionalities, and the first set and the second set are mirror images of each other relative to the plate, the mirror images being in terms of the functionalities of the respective IC dies.

Example 11 provides the microelectronic assembly of example 10, in which: the first set and the second set each include a system-on-chip (SOC) IC die, a voltage regulator (VR) IC die, and at least one memory IC die, the VR IC die is in direct contact with the SOC IC die and the at least one memory IC die in each of the first set and the second set, and the SOC IC dies of the first set and the second set are in direct contact with the plate.

Example 12 provides the microelectronic assembly of any one of examples 1-11, in which: the plate is a first plate, the second IC die is on a first side of the first set, the second set and the first plate, the microelectronic assembly further includes a second plate on a second side of the first set, the second set and the first plate, the second side is opposite to the first side, and the second plate is parallel to the planar interface of the second IC die and perpendicular to the first plate.

Example 13 provides the microelectronic assembly of example 12, in which the second plate includes a metal.

Example 14 provides the microelectronic assembly of example 12 or 13, in which: the second plate is directly coupled to the second side by a thermal interface material (TIM).

Example 15 provides the microelectronic assembly of example 14, in which the TIM includes solder.

Example 16 provides the microelectronic assembly of example 14, in which the TIM includes at least one polymer.

Example 17 provides the microelectronic assembly of any one of examples 12-16, in which: the first set, the second set, the first plate and the second IC die includes a first sub-assembly, a second sub-assembly includes other ones of the first set, the second set, the first plate and the second IC die, the microelectronic assembly further includes the second sub-assembly on an opposite side of the second plate, and the second plate is directly coupled to the second sub-assembly and is distant from the second IC die of the second sub-assembly.

Example 18 provides the microelectronic assembly of example 17, in which: the first sub-assembly and the second sub-assembly with the second plate therebetween form a third sub-assembly, a fourth sub-assembly includes other ones of the first sub-assembly, the second sub-assembly and the second plate therebetween, and the microelectronic assembly further includes an electrical board between one of the second IC dies of the third sub-assembly and another of the second IC dies of the fourth sub-assembly.

Example 19 provides the microelectronic assembly of any one of examples 12-18, further including a third IC die adjacent to the second set and directly coupled to the second IC die, in which the third IC die is arranged such that the planar interface of the third IC die is parallel to the planar interface of the second IC die and perpendicular to the planar interfaces of the first IC dies.

Example 20 provides the microelectronic assembly of example 19, in which the third IC die is thermally coupled to the second plate by a TIM.

Example 21 provides the microelectronic assembly of example 19, further including a third plate of silicon between the second plate and the third IC die, in which the third plate is bonded to the third IC die and coupled to the second plate by a TIM.

Example 22 provides the microelectronic assembly of example 19, in which: the second plate includes a pedestal aligned with the third IC die, and the third IC die is coupled to the pedestal by a TIM.

Example 23 provides an integrated circuit (IC) die assembly, including a first set including one or more of first IC dies; a second set including another one or more of the first IC dies; a plate between, and in direct contact with, the first set and the second set; and a second IC die coupled to the first set, the second set, and the plate, in which: each IC die includes a substrate of semiconductor material and an interconnect region including metallization in interlayer dielectric (ILD), the substrate and the interconnect region share a planar interface, the first IC dies and the second IC die are arranged with the planar interfaces of the first IC dies parallel to each other and orthogonal to the planar interface of the second IC die, and the plate includes structures to transfer heat away from the first set and the second set.

Example 24 provides the IC die assembly of example 23, in which the structures are channels for a liquid coolant to transfer heat in a direction away from the second IC die.

Example 25 provides the IC die assembly of example 24, in which the channels have a serpentine shape.

Example 26 provides the IC die assembly of example 25, in which the serpentine shape is parallel to the planar surface of the second IC die in any cross-section perpendicular to the planar surface of the second IC die.

Example 27 provides the IC die assembly of example 25, in which the serpentine shape is perpendicular to the planar surface of the second IC die in any cross-section perpendicular to the planar surface of the second IC die.

Example 28 provides the IC die assembly of any one of examples 24-27, in which the channels include copper.

Example 29 provides the IC die assembly of example 23, in which the structures are Peltier devices to cool the first set and the second set.

Example 30 provides the IC die assembly of example 23, in which the structures are acoustic resonators to transfer heat in a direction away from the second IC die.

Example 31 provides the IC die assembly of any one of examples 23-30, in which: the first set and the second set each include a first compute IC die, a second compute IC die, and a stack of several memory IC dies, the second compute IC die is in direct contact with the first compute IC die and the stack of several memory IC dies in each of the first set and the second set, and the first compute IC dies of the first set and the second set are in direct contact with the plate.

Example 32 provides the IC die assembly of any one of examples 23-31, in which: the plate is a first plate, the second IC die is on a first side of the first set, the second set and the first plate, the IC die assembly further includes a second plate on a second side of the first set, the second set and the first plate, the second side is opposite to the first side, and the second plate is parallel to the planar interface of the second IC die and perpendicular to the first plate.

Example 33 provides the IC die assembly of example 32, in which: the structures in the first plate are first structures, and the second plate includes second structures that interface with the first structures to transfer heat away from the first set and the second set.

Example 34 provides the IC die assembly of example 33, in which: the first structures are channels with ports on a side of the first plate distant from the second IC die, and the second structures are manifolds that interface with the ports for permitting flow of fluid between the second structures and the first structures.

Example 35 provides the IC die assembly of any one of examples 32-34, in which: the first set, the second set, the first plate and the second IC die includes a first sub-assembly, a second sub-assembly includes other ones of the first set, the second set, the first plate and the second IC die, the IC die assembly further includes the second sub-assembly on an opposite side of the second plate, and the second plate is directly coupled to the second sub-assembly and is distant from the second IC die of the second sub-assembly.

Example 36 provides a microelectronic assembly, including a set including one or more of first integrated circuit (IC) dies; a second IC die coupled to the first set; and a third IC die adjacent to the set of first IC dies and coupled to the second IC die, in which: each IC die includes a substrate of semiconductor material and an interconnect region including metallization in interlayer dielectric (ILD), the substrate and the interconnect region share a planar interface, and the first IC dies, the second IC die and the third IC die are arranged such that the planar interfaces of the first IC dies are parallel to each other and orthogonal to the planar interfaces of the second IC die and the third IC die, and the planar interfaces of the second IC die and the third IC die are parallel to each other.

Example 37 provides the microelectronic assembly of example 36, further including a plate on a side of the first IC dies opposite to the second IC die, in which the plate is parallel to the planar interfaces of the second IC die and the third IC die.

Example 38 provides the microelectronic assembly of example 37, in which: the plate is a first plate, the microelectronic assembly further includes a second plate of silicon between the first plate and the third IC die, and the second plate is bonded to the third IC die and coupled to the first plate by a TIM.

Example 39 provides the microelectronic assembly of example 38, in which the first plate includes openings around the first IC dies.

Example 40 provides the microelectronic assembly of any one of examples 37-39, in which the plate includes metal.

Example 41 provides the microelectronic assembly of any one of examples 36-40, in which the first IC dies are memory dies, the second IC die is a base die, and the third IC die is a SOC die.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A microelectronic assembly, comprising:
a first set comprising one or more of first integrated circuit (IC) dies;
a second set comprising another one or more of the first IC dies;
a plate in direct contact with the first set and the second set; and
a second IC die coupled to the first set, the second set, and the plate, wherein:
each IC die comprises a substrate of semiconductor material and an interconnect region including metallization in interlayer dielectric (ILD),
the substrate and the interconnect region share a planar interface, and
the first IC dies and the second IC die are arranged with the planar interfaces of the first IC dies parallel to each other and orthogonal to the planar interface of the second IC die.

2. The microelectronic assembly of claim 1, wherein the plate comprises at least one of: (i) silicon, (ii) a compound comprising silicon and carbon, and (iii) crystalline carbon.

3. The microelectronic assembly of claim 1, wherein the plate includes channels that permit flow of a fluid.

4. The microelectronic assembly of claim 1, wherein:
the first set and the second set each comprise IC dies having different structures corresponding to different functionalities,
the first set and the second set are mirror images of each other relative to the plate, the mirror images being in terms of the functionalities of the respective IC dies.

5. The microelectronic assembly of claim 1, wherein:
the plate is a first plate,
the second IC die is on a first side of the first set, the second set and the first plate,
the microelectronic assembly further comprises a second plate on a second side of the first set, the second set and the first plate,
the second side is opposite to the first side, and
the second plate is parallel to the planar interface of the second IC die and perpendicular to the first plate.

6. The microelectronic assembly of claim 5, wherein: the second plate is directly coupled to the second side by a thermal interface material (TIM).

7. The microelectronic assembly of claim 5, wherein:
the first set, the second set, the first plate and the second IC die comprises a first sub-assembly,
a second sub-assembly comprises other ones of the first set, the second set, the first plate and the second IC die,
the microelectronic assembly further comprises the second sub-assembly on an opposite side of the second plate, and
the second plate is directly coupled to the second sub-assembly and is distant from the second IC die of the second sub-assembly.

8. The microelectronic assembly of claim 7, wherein:
the first sub-assembly and the second sub-assembly with the second plate therebetween form a third sub-assembly,
a fourth sub-assembly comprises other ones of the first sub-assembly, the second sub-assembly and the second plate therebetween,
the microelectronic assembly further comprises an electrical board between one of the second IC dies of the third sub-assembly and another of the second IC dies of the fourth sub-assembly.

9. The microelectronic assembly of claim 5, further comprising a third IC die adjacent to the second set and directly coupled to the second IC die, wherein the third IC die is arranged such that the planar interface of the third IC die is parallel to the planar interface of the second IC die and perpendicular to the planar interfaces of the first IC dies.

10. An integrated circuit (IC) die assembly, comprising:
a first set comprising one or more of first IC dies;
a second set comprising another one or more of the first IC dies;
a plate between, and in direct contact with, the first set and the second set; and
a second IC die coupled to the first set, the second set, and the plate, wherein:
each IC die comprises a substrate of semiconductor material and an interconnect region including metallization in interlayer dielectric (ILD),
the substrate and the interconnect region share a planar interface,
the first IC dies and the second IC die are arranged with the planar interfaces of the first IC dies parallel to each other and orthogonal to the planar interface of the second IC die, and
the plate comprises structures to transfer heat away from the first set and the second set.

11. The IC die assembly of claim 10, wherein the structures are channels for a liquid coolant to transfer heat in a direction away from the second IC die.

12. The IC die assembly of claim 10, wherein:
the plate is a first plate,
the second IC die is on a first side of the first set, the second set and the first plate,
the IC die assembly further comprises a second plate on a second side of the first set, the second set and the first plate,
the second side is opposite to the first side, and
the second plate is parallel to the planar interface of the second IC die and perpendicular to the first plate.

13. The IC die assembly of claim 12, wherein:
the structures in the first plate are first structures,
the second plate comprises second structures that interface with the first structures to transfer heat away from the first set and the second set.

14. The IC die assembly of claim 13, wherein:
the first structures are channels with ports on a side of the first plate distant from the second IC die, and
the second structures are manifolds that interface with the ports for permitting flow of fluid between the second structures and the first structures.

15. The IC die assembly of claim 12, wherein:
the first set, the second set, the first plate and the second IC die comprises a first sub-assembly,
a second sub-assembly comprises other ones of the first set, the second set, the first plate and the second IC die,
the IC die assembly further comprises the second sub-assembly on an opposite side of the second plate, and
the second plate is directly coupled to the second sub-assembly and is distant from the second IC die of the second sub-assembly.

16. A microelectronic assembly, comprising:
a set comprising one or more of first integrated circuit (IC) dies;
a second IC die coupled to the first set; and
a third IC die adjacent to the set of first IC dies and coupled to the second IC die, wherein:
each IC die comprises a substrate of semiconductor material and an interconnect region including metallization in interlayer dielectric (ILD),
the substrate and the interconnect region share a planar interface, and
the first IC dies, the second IC die and the third IC die are arranged such that the planar interfaces of the first IC dies are parallel to each other and orthogonal to the planar interfaces of the second IC die and the third IC die, and the planar interfaces of the second IC die and the third IC die are parallel to each other.

17. The microelectronic assembly of claim 16, further comprising:
a plate on a side of the first IC dies opposite to the second IC die, and
the plate is parallel to the planar interfaces of the second IC die and the third IC die.

18. The microelectronic assembly of claim 17, wherein:
the plate is a first plate, and the microelectronic assembly further comprises a second plate of silicon between the first plate and the third IC die, and
the second plate is bonded to the third IC die and coupled to the first plate by a TIM.

19. The microelectronic assembly of claim 18, wherein the first plate includes openings around the first IC dies.

20. The microelectronic assembly of claim 16, wherein the first IC dies are memory dies, the second IC die is a base die, and the third IC die is a SOC die.
